(19) United States
(12) Patent Application Publication
(10) Pub. No.: US 2024/0038702 A1
(43) Pub. Date: Feb. 1, 2024

(54) HIGH-PERFORMANCE HYBRID BONDED INTERCONNECT SYSTEMS

(71) Applicant: ADEIA SEMICONDUCTOR BONDING TECHNOLOGIES INC., San Jose, CA (US)

(72) Inventor: Cyprian Emeka Uzoh, San Jose, CA (US)

(21) Appl. No.: 17/815,500

(22) Filed: Jul. 27, 2022

(51) Int. Cl. H01L 23/00; H01L 25/065; H01L 23/538; H01L 21/66; H01L 25/00

(52) U.S. Cl. CPC H01L 24/08; H01L 25/0652; H01L 23/5381; H01L 22/32; H01L 24/80; H01L 25/50; H01L 2224/08145; H01L 2224/08225; H01L 2224/80895; H01L 2224/80896; H01L 2225/06572; H01L 2225/06582; H01L 2225/06596

(57) ABSTRACT

A high-performance hybrid bonded interconnect structure and a method for producing a high-performance hybrid bonded interconnect structure is discloses. The interconnect structure may comprise a first plurality of die stacks bonded to a carrier. A protective layer may be provided over at least a portion of the first plurality of die stacks and the second plurality of die stacks. A bridging layer comprising a conductive interconnect may provide electrical communication between the plurality of die stacks.

### BACKGROUND

### Field of the Invention

The field relates to high performance three dimensional bonded structures and methods for forming high performance three dimensional bonded structures.

### Description of the Related Art

In semiconductor device packaging arrangements, stacks of integrated device dies are used in many applications. For example, three-dimensional (3D) integration techniques often utilize packages in which two or more integrated device dies are stacked on top of and electrically connected to one another. Conventional methods for producing 3D integrated devices can limit product yield due to stress imparted to both the dies and the substrate during assembly. Accordingly, there remains a continuing need for improved systems and methods for stacking integrated device dies.

### SUMMARY

In one embodiment, a bonded structure can include: a carrier; a first plurality of die stacks, each die stack comprising a plurality of dies, each die stack of the first plurality of die stacks bonded to the carrier; a protective layer over at least a portion of the first plurality of die stacks; and a bridging layer comprising a nonconductive bridge layer and a lateral conductive interconnect; wherein the lateral conductive interconnect provides electrical communication between the first plurality of die stacks.

In some embodiments, the bonded structure can include a plurality of contact features at least partially embedded in the nonconductive bridge layer, wherein the lateral conductive interconnect provides electrical communication between at least two of the plurality of contact features. In some embodiments, the bonded structure can include at least one die stack directly bonded without an adhesive to the bridging layer. In some embodiments, the bonded structure can include a second plurality of die stacks directly bonded to the bridging layer and a bridging element directly bonded to the second plurality of die stacks. In some embodiments, the bonded structure can include at least one test pad at least partially embedded in the bridging layer, wherein the test pad is in electrical communication with the first plurality of stacks and the second plurality of stacks. In some embodiments, the bonded structure can include a bridging element directly bonded, without an adhesive, to the bridging layer. In some embodiments, the bonded structure can include a cavity between a first stack and a second stack. In some embodiments, each stack of the first plurality of stacks comprises a first die bonded to a second die, without an adhesive. In some embodiments, a first nonconductive bonding layer of at least one stack of the plurality stacks is directly bonded to a second nonconductive bonding layer of the carrier without an intervening adhesive, wherein a first contact feature of at least one stack of the plurality stacks is directly bonded to a second contact feature of the carrier without an intervening adhesive. In some embodiments, a material of the protective layer is the same as a material of the bridging layer.

In another embodiment, a bonded structure can include: a first die stack comprising a first plurality of dies; a second die stack comprising a second plurality of dies; a protective layer disposed at least about lateral sides of the first and second die stacks and between the first and second die stacks; and a bridging layer disposed over the first die stack, the second die stack, and the protective layer, the bridging layer providing electrical communication between the first and second die stacks.

In some embodiments, the first plurality of dies within the first die stack are direct hybrid bonded. In some embodiments, the second plurality of dies within the second die stack are direct hybrid bonded. In some embodiments, the first die stack and the second die stack are direct hybrid bonded to a carrier. In some embodiments, the first die stack and the second die stack are direct hybrid bonded to a bridging element. In some embodiments, the bonded structure can include a third die stack comprising a third plurality of dies, wherein the third die stack is direct hybrid bonded to the bridging layer, and a fourth die stack comprising a fourth plurality of dies, wherein the fourth die stack is direct hybrid bonded to the bridging layer. In some embodiments, the bonded structure can include a bridging element bonded to the third die stack and the fourth die stack. In some embodiments, the bonded structure can include at least one test pad embedded in the bridging layer, the test pad configured to be in electrical communication with the first die stack, the second die stack, the third die stack and the fourth die stack.

In another embodiment, a method for forming a bonded structure is disclosed. The method can include: directly bonding a first plurality of stacks to a carrier, wherein each stack of the first plurality of stacks comprises at least one die in contact with the carrier; providing a protective layer at least partially over at least a portion of the plurality of stacks; planarizing the protective material; and forming a nonconductive bridging layer comprising a nonconductive bridge layer and a lateral conductive interconnect, wherein the lateral conductive interconnect provides electrical communication between the first plurality of die stacks.

In some embodiments, the method can include forming a first plurality of contact features at least partially embedded in the nonconductive bridge layer, wherein the lateral conductive interconnect provides electrical communication between at least two of the first plurality of contact features. In some embodiments, planarizing the protective material exposes contact features of the plurality of stacks. In some embodiments, each stack comprises at least a first die bonded to a second die. In some embodiments, the method can include bonding a second plurality of stacks to the nonconductive bridging layer. In some embodiments, each stack of the second plurality of stacks is configured to be in electrical communication with each stack of the first plurality of stacks. In some embodiments, a nonconductive bridging element is directly bonded to the second plurality of stacks. In some embodiments, a bridging element is directly bonded to the nonconductive bridging layer. In some embodiments, providing a protective layer further comprises forming a cavity between a first stack and a second stack. In some embodiments, the nonconductive bridging layer further comprises testing pads configured to be in electrical communication with the first plurality of stacks.

In another embodiment, a bonded structure can include: a carrier; a first die stack having a first top die and a first bottom die, the first bottom die of the first stack bonded to the carrier; a bridging layer comprising a nonconductive layer and a conductive interconnect, the bridging layer disposed over the first top die of the first stack; and a second die stack having a second bottom die bonded (e.g., direct hybrid bonded) to an upper surface of the bridging layer, wherein the conductive interconnect of the bridging layer provides electrical communication between the first and second die stacks.

In some embodiments, the bonded structure can include a third die stack bonded to the carrier, the bridging layer disposed over a third top die of the third stack.

In another embodiment, a bonded structure can include: a carrier having a nonconductive layer and conductive features at least partially embedded in the nonconductive layer; a first die stack having a first top die and a first bottom die, the first top and first bottom dies of the first die stack each having a respective nonconductive layer and conductive features, the first bottom die of the first die stack bonded to the carrier; a bridging layer comprising a nonconductive layer and a conductive interconnect, the bridging layer disposed over the first top die of the first stack; and a second die stack having a second bottom die bonded (e.g., direct hybrid bonded) to an upper surface of the bridging layer, wherein the conductive interconnect of the bridging layer provides electrical communication between the first and second die stacks.

In some embodiments, the bonded structure can include a third die stack bonded to the carrier, the bridging layer disposed over a third top die of the third stack. In some embodiments, the conductive interconnect of the bridging layer comprises a printed wire. In some embodiments, the bonded structure can include a wire bond that connects the first and second die stacks.

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIGS. 1A-1B schematically show conventionally designed microelectronic structures.

FIGS. 2A-2G schematically show example methods for microelectronic device manufacturing.

FIGS. 3A-3H illustrate a method for forming a microelectronic structure, according to various embodiments.

FIGS. 4A-4F illustrate a method for forming a microelectronic structure, according to various embodiments.

### DETAILED DESCRIPTION

Various embodiments disclosed herein enable multiple arrays or stacks of singulated integrated device dies (e.g., semiconductor devices, integrated circuit devices, etc.) to be mounted, via direct bonding, to a carrier (e.g., a package substrate, a wafer, another integrated device die, substrate etc.) and to be in electrical communication with each other. Forming multiple stacks, e.g., arrays, of directly bonded dies on a carrier may cause significant stress within the carrier material. Stress within the carrier material may decrease the flatness of the device and affect device yield during down-stream production steps. Moreover, electrical communication between individual dies of a first stack with individual dies of a second stack may be challenging because the only communication path between the first stack and the second stack is through the carrier. Thus, communication between two dies in adjacent die stacks may experience lag or signal delays.

In some embodiments, a protective material, which may comprise one or more protective layers, can be applied over and around the stack of dies to lower the stress that the stack cause in the carrier material and improve carrier flatness. Moreover, various embodiments disclosed herein facilitate the efficient electrical communication between individual dies within the stack through the use of bridging layers and/or bridging elements. Bridging layers and/or bridging elements may be produced on top of multiple stacks and be configured to allow one stack to electrically communicate with the other stacks through the bridging layer or bridging elements. In some embodiments, a bonded bridging die (e.g., a semiconductor device, integrated circuit device, etc.) may electrically connect a first die stack with a second die stack. In some embodiments, a nonconductive (e.g., dielectric) bridging layer may be formed (e.g., deposited) and patterned with electrical contacts and traces to electrically connect multiple adjacent stacks of dies.

Accordingly, in various embodiments, a first die may be bonded (e.g., using hybrid direct bonding techniques, such as the DBI® techniques used by Xperi Corporation of San Jose, California) to bonding surfaces of a carrier such as a substrate (e.g., a wafer, a printed circuit board, etc.). In some embodiments, a first stack of dies may be formed by directly bonding a series of dies on top of the first die. In some embodiments, each die of a stack is in electrical communication with every other die within the same stack. Through substrate vias (TSVs) can provide vertical electrical communication between vertically-adjacent dies within a stack. In some embodiments, a second stack of dies may be bonded on the carrier laterally adjacent to the first stack of dies. As in the first stack of dies, each individual die within the second stack of dies may be in electrical communication with each of the other dies within the second stack of dies. In various embodiments, one or more protective support materials may be provided over the first and the second stacks of dies. In some embodiments, the support materials may be planarized using a conventional polishing or etching process, such as a chemical mechanical polishing (CMP) process. In some embodiments, a bridging layer or layers may be deposited on the first and second die stacks. In some embodiments, electrical contact structures and/or traces may be formed on, through, and/or within the bridging layer or layers such that the top-most die of the first stack is in electrical communication with the top-most die of the second stack via the bridging layers.

Another advantage of forming a bonded stacked structure according to the disclosed embodiments is the availability of using efficient direct bonding to create larger and more complex 3D stack structures while maintaining low carrier stress and decreasing signal path lengths while optimizing production yield. After depositing a bridging layer, in some embodiments, further stacks may be directly bonded on top of the bridging dielectric layer. In some embodiments, a bridging element (e.g., bridging die) may additionally or alternatively be provided to bridge the top-most dies of adjacent stacks. In some embodiments, further stacks bonded to the top of the bridging dielectric layer or bridging die may be in electrical communication with the first and second die stacks via the bridging dielectric layer or bridging die.

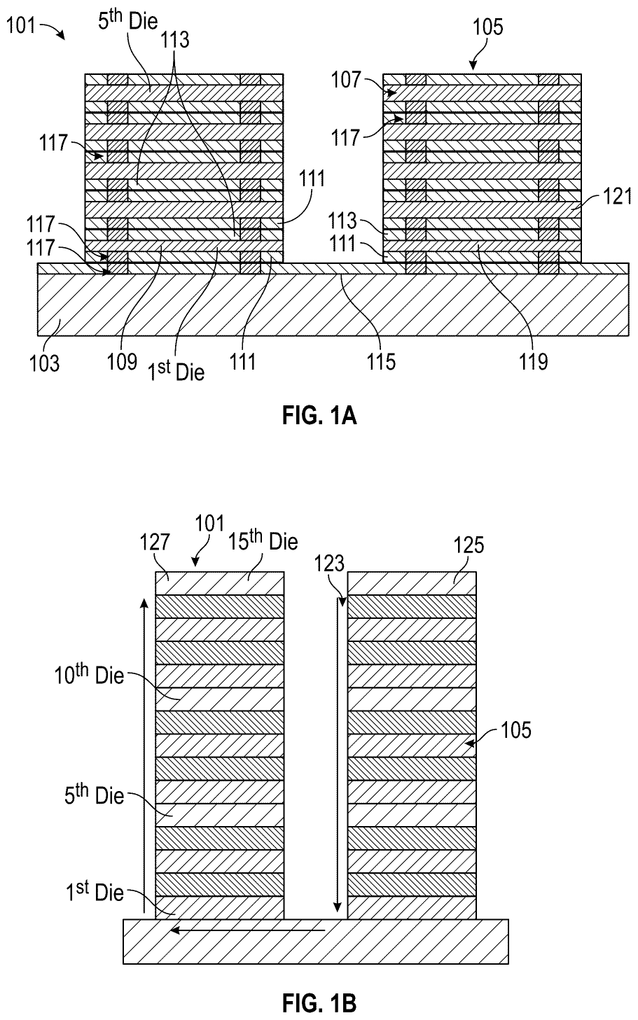

FIGS. 1A-1B schematically show conventional bonded structures on a carrier (e.g., a wafer, a printed circuit board, etc.). Conventionally, a first stack of dies 101 (e.g., semiconductor devices, integrated circuit devices, etc.) is attached to a carrier 103 (e.g., a substrate, a wafer, another integrated device die, etc.) via a carrier bonding layer 115. In some arrangements, the stack 101 can be attached with an adhesive, such as solder. In other arrangements, the stack 101 can be direct hybrid bonded to the carrier 103 without an adhesive. In various embodiments, the carrier 103 can comprise a wafer, a singulated integrated device die, a semiconductor interposer, a reconstituted element, etc. Carrier bonding layer 115 may have a plurality of conductive contacts 117 at least partially embedded in the layer. Although depicted as a single layer, carrier bonding layer 115 may comprise one or more dielectric layers. A second stack of dies 105 may be laterally adjacent to the first stack of dies 101 and attached to carrier 103. In some arrangements, the stack 101 can be attached with an adhesive, such as solder. In other arrangements, the stack 105 can be direct hybrid bonded to the carrier 103 without an adhesive.

Both the first 101 and second 105 stack of dies may comprise multiple individual dies 107 bonded to one another. For instance, in FIG. 1A, the first stack of dies 101 comprises five (5) individual dies 107 bonded to one another. A first die 109 may comprise a frontside bonding layer 111 and a backside bonding layer 113. Both the frontside 111 and backside 113 bonding layers may comprise one or more dielectric layers and may have a plurality of conductive contacts 117 at least partially embedded in both the frontside 111 and backside 113 dielectric layers. A second die 119, comprising a frontside bonding layer 111 and a backside bonding layer 113, wherein a plurality of conductive contacts may be at least partially embedded in layers 111 and 113, may be bonded to the first die 109. Further dies 107 may be bonded to the first 109 and second 119 dies to form the first stack 101. A second stack 105, similar to the first stack, may be formed on a laterally adjacent position on carrier 103. Each die 107 of the second stack 105 may have a front side 111 and backside 113 bonding layer as well as a plurality of conductive contacts 117 that may be at least partially embedded in the frontside 111 and backside 113 bonding layers. Like the first stack 101, the second stack 105 may comprise a stack of dies 107, wherein the first die 119 of the second stack 105 is attached (e.g., direct hybrid bonded) to the carrier 103, a second die 121 of the second stack 105 is bonded (e.g., direct hybrid bonded) to the first die 119, and so on. This stacked bonding configuration may be repeated until a desired number of dies are bonded into the second stack 105. Each die (or each die except the topmost dies in some arrangements) may include through-substrate vias (TSVs) (not shown) to provide vertical electrical communication between vertically-adjacent dies. As the number of dies within the first 101 and second 105 stack increases, so too does the stress on the carrier 103 as well as the communication path lengths between the dies of the first 101 and second 105 stacks.

FIG. 1B schematically illustrates a first stack 101 and second stack 105 bonded to a carrier 103. In the configuration of FIG. 1B, the stress on the carrier 103 may be high, and may lead to significant bending of the carrier 103 (non flatness). Moreover, the signal paths 123 between the topmost die (e.g., the 15^{th} die 125) of the second stack 105 to the topmost die (e.g., the 15^{th} die 127) of the first stack 101 is long. For example, for 50 μm thick directly bonded dies, the electrical path between the 15^{th} die 127 of the first stack 101 and the bonding layer 115 of the carrier 103 is about 700 μm (50×14 dies). From the foregoing, the electrical path between the 15^{th} die 127 of the first stack 101 and the 15^{th} die 125 of the second stack 105 is more than 1400 μm, when the lateral trace in the bonding layer of the carrier is taken into consideration. Long signal paths 123 may cause significant delay and slow signal processing when communicating between distal dies, such as die 125 and 127. Moreover, all electrical communication between the second stack 105 and the first stack 101 travels along signal paths 123 through the carrier 103. Furthermore, there is no lateral support to support the first 101 and second 105 stacks. This lack of lateral support may diminish downstream yield of final products using devices with large first 101 and second 105 stacks.

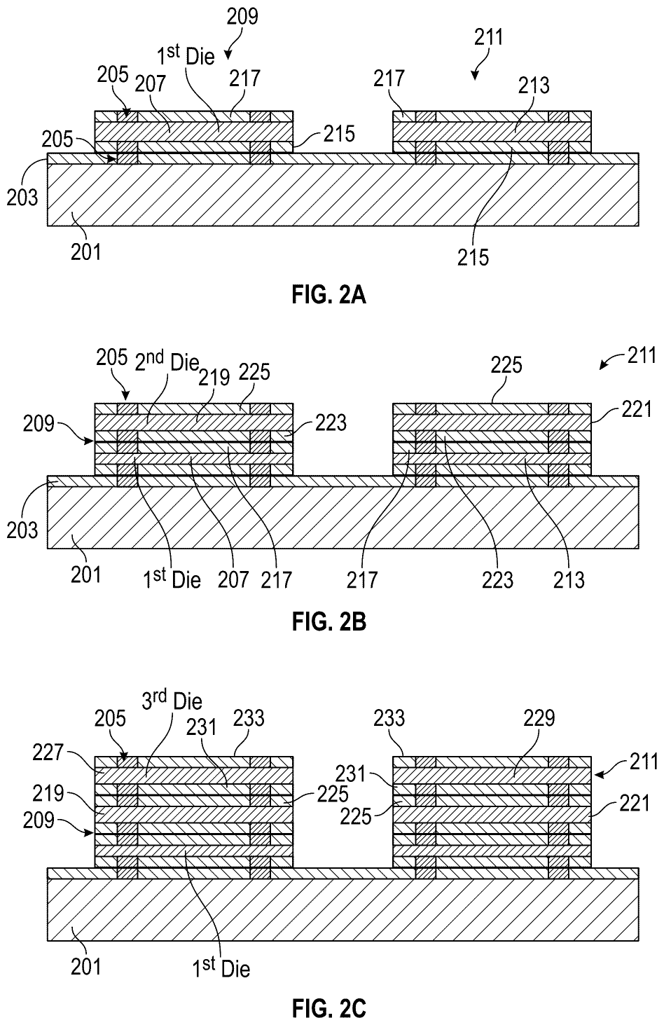

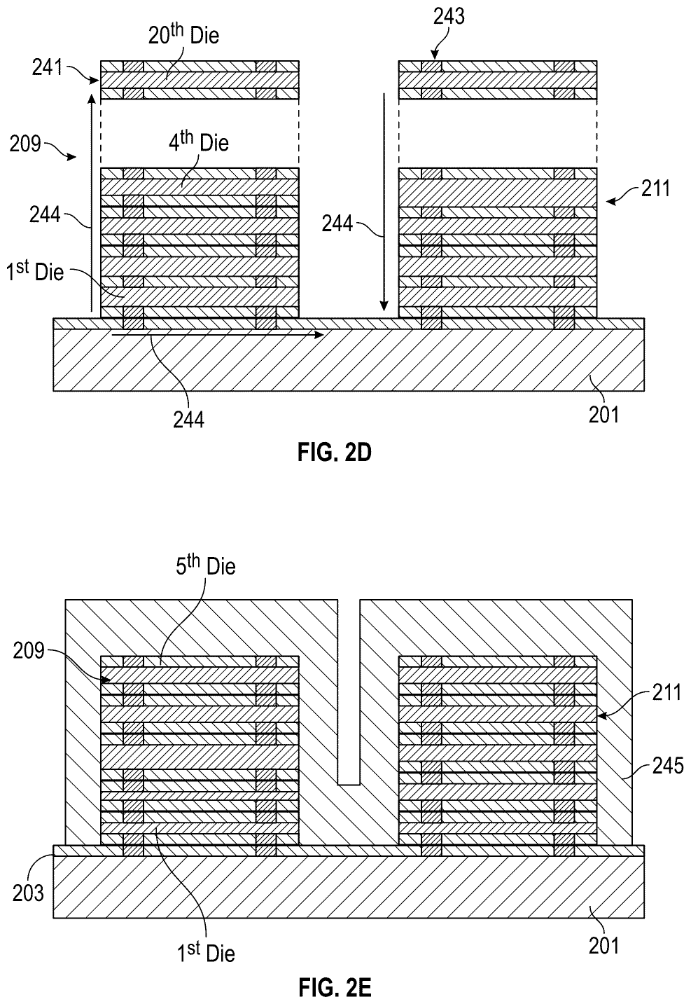

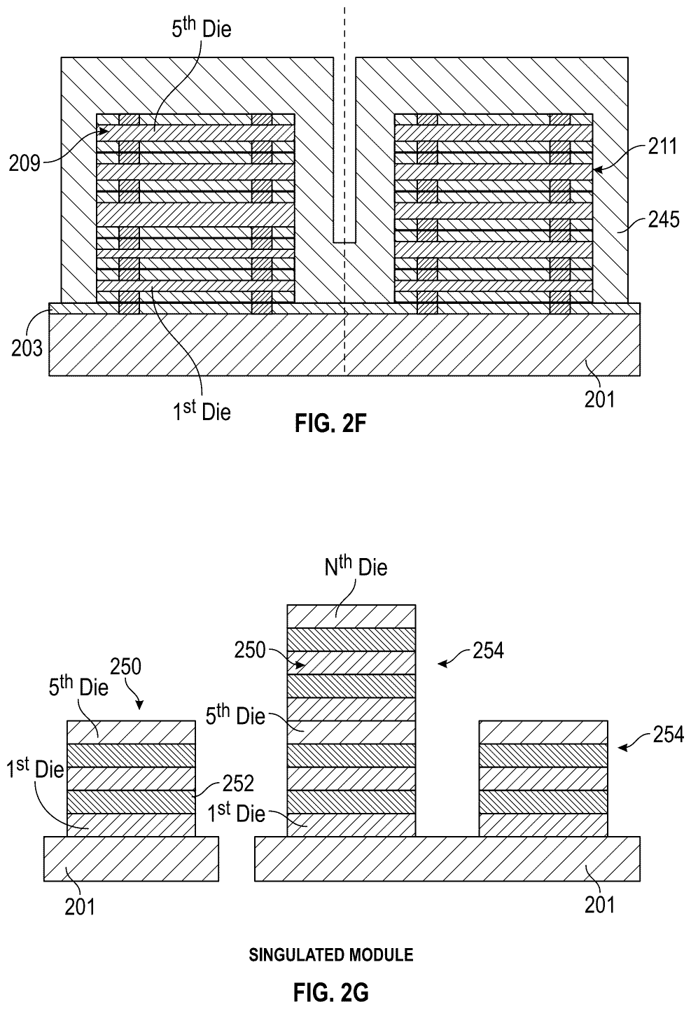

FIGS. 2A-2G schematically illustrate an example process for forming multiple stacks of dies (e.g., semiconductor devices, integrated circuit devices, etc.) on a carrier 201 (e.g., a wafer, a substrate, a die, etc.). FIG. 2A schematically illustrates a carrier 201 with a first stack 209 and a second stack 211 each with one die 207 and 213. In some embodiments, a carrier 201 comprises a bonding layer 203, e.g., one or more dielectric layers with at least partially embedded conductive contacts 205. Although schematically shown to be a single layer, it should be understood that bonding layer 203 may comprise multiple dielectric layers. A plurality of electrical contacts 205 may be at least partially embedded in bonding layer 203. A first die 207 of a first stack 209 and a first die 213 of a second stack 211 may be directly hybrid bonded to the carrier 201. The first die 207 of the first stack 209 and the first die 213 of the second stack 211 may comprise a frontside 215 and backside 217 bonding layer. Both the frontside 215 and backside 217 bonding layers may comprise one or more dielectric layers or sub-layers. A plurality of conductive contacts 205 may be at least partially embedded in both the frontside 215 and backside 217 bonding layers. Although not shown, a plurality of through substrate vias (TSVs) can provide electrical communication between the contacts 205 on the frontside 215 bonding layers and the contacts 205 on the backside 217 bonding layers.

In FIG. 2B, a pair of second dies 219 and 221 (e.g., semiconductor devices, integrated circuit devices, etc.) may be direct hybrid bonded to the first die 207 of the first stack 209 and the first die 213 of the second stack 211 respectively. In some embodiments, the pair of second dies 219 and 221 each comprise a frontside bonding layer 223 and a backside bonding layer 225. In some embodiments, one or both of frontside bonding layer 223 and backside bonding layer 225 may be dielectric layers with at least partially embedded conductive contacts 205. Although illustrated as single layers 223 and 225, it should be understood that layers 223 and 225 may comprise multiple dielectric layers or sub-layers. The pair of second dies 219 and 221 may be directly bonded to the pair of first dies 207 and 213 respectively via bonding layers 217 and 223. Although not shown, a plurality of through substrate vias (TSVs) can provide electrical communication between the contacts 205 on the frontside 223 bonding layers and the contacts 205 on the backside 225 bonding layers.

In FIG. 2C, a pair of third dies 227 and 229 may be directly bonded to the pair of second dies 219 and 221 respectively. In some embodiments, the pair of third dies 227 and 229 each comprise a frontside 231 and backside 233 bonding layer. In some embodiments, one or both of frontside 231 and backside 233 bonding layers may be dielectric layers with at least partially embedded conductive contacts 205. Although illustrated as single layers 231 and 233, it should be understood that layers 231 and 235 may comprise multiple dielectric layers. In some embodiments, the plurality of conductive contacts 205 may be at least partially embedded in one or both the frontside 231 and backside 233 bonding layers. The frontside bonding layer 231 of the pair of third dies 227 and 229 may be bonded to the backside bonding layer 225 of the pair of second dies 219 and 221 respectively. Although not shown, a plurality of through substrate vias (TSVs) can provide electrical communication between the contacts 205 on the frontside 231 bonding layers and the contacts 205 on the backside 233 bonding layers.

In FIG. 2D, further pairs of dies 241 and 243 may be added to the stacks in a similar fashion to FIGS. 2A-C. Further dies 241 and 243 may be bonded to the dies of the first stack 209 and the second stack 211. Any suitable numbers of dies may be provided in each stack 209, 211. Each stack 209, 211 may include the same number of stacked dies or a different number of stacked dies. As more dies 241 and 243 may be bonded to the first stack 209 and the second stack 211, the longer the electrical communication paths 244, e.g., signal paths, between the dies 245 of the first stack 209 and the dies 247 of the second stack 211 become. Longer electrical communication paths 244 may lead to slower processing speeds between the stacks. Moreover, because the first stack 209 can only communicate with the second stack 211 via carrier 201, signal paths remain long and signal speed lowers with the addition of more dies 241 and 243 to the first stack 209 and second stack 211 respectively. For example, the topmost die of the first stack 209 communicates with the topmost die of the second stack 211 by way of TSVs formed through the underlying dies of the first stack 209, traces in the carrier 201, and TSVs formed through the underlying dies of the second stack 211. The long signal pathway 244 between the two topmost dies (and between other dies in the stacks 209, 211) introduces lags and delays that can reduce electrical performance.

In FIG. 2E, a protective layer 245 may be deposited over and around the first stack 209 and the second stack 211 and over exposed portions of the carrier dielectric layer 203. Protective layer 245 may comprise a coating or molding compound that provides some lateral support to the first stack 209 and the second stack 211 during singulation or planarization. For example, the protective layer 245 can comprise an organic polymer, such as an epoxy. In other embodiments, the protective layer 245 may comprise one or more inorganic dielectric materials (e.g., silicon oxide). Still in some embodiments the protective layer 245 may comprise a lamination of multiple layers, including, e.g., inorganic and organic dielectric layers.

In FIG. 2F, the first stack 209 and the second stack 211 may be singulated. During singulation, protective layer 245 may provide some lateral support and protection to the first stack 209 and the second stack 211. However, because of the stress that the first stack 209 and the second stack 211 produce in the carrier 201, the carrier 201 might experience significant stress during singulation, which may lead to cracking and lower yield.

In FIG. 2G, singulated modules 250 may be produced from pluralities of stacked dies. The modules may comprise a singular stack of dies 252 or multiple stacks of dies 254 mounted, e.g., bonded, to a carrier 201. In modules 250 with multiple stacks of dies 254, all communication between adjacent stacks of dies 252 occurs via the carrier 201. Moreover, because there is little lateral support between the multiple stacks of dies 254, the carrier 201 may deform or develop defects such as cracks because of stress produced from the multiple stacks of dies 254. Carrier 201 deformation may lead to lower efficiency and yield when producing devices using modules 250 with multiple stacks of dies 252 or 254.

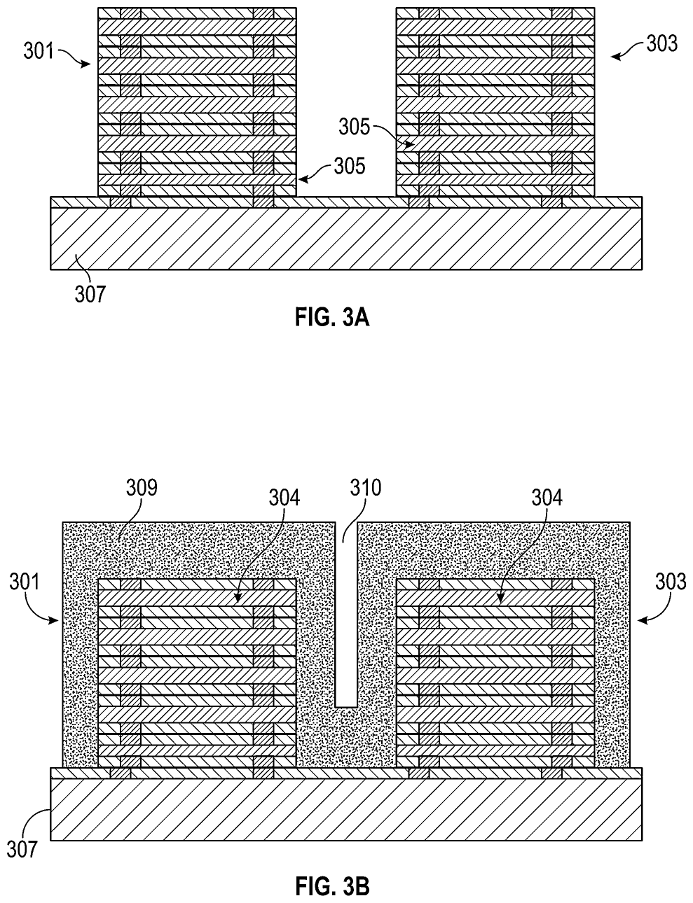

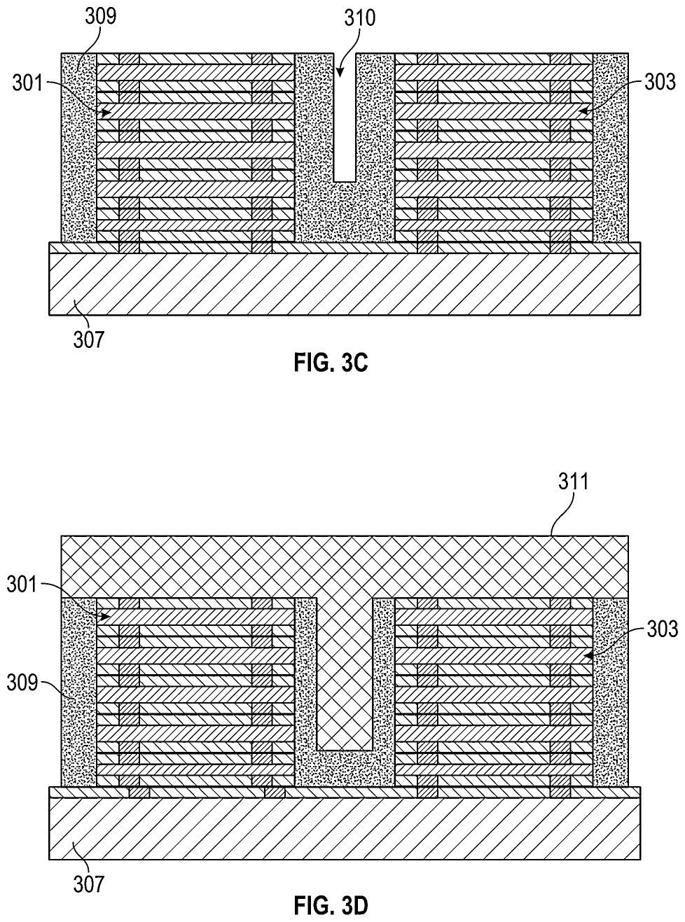

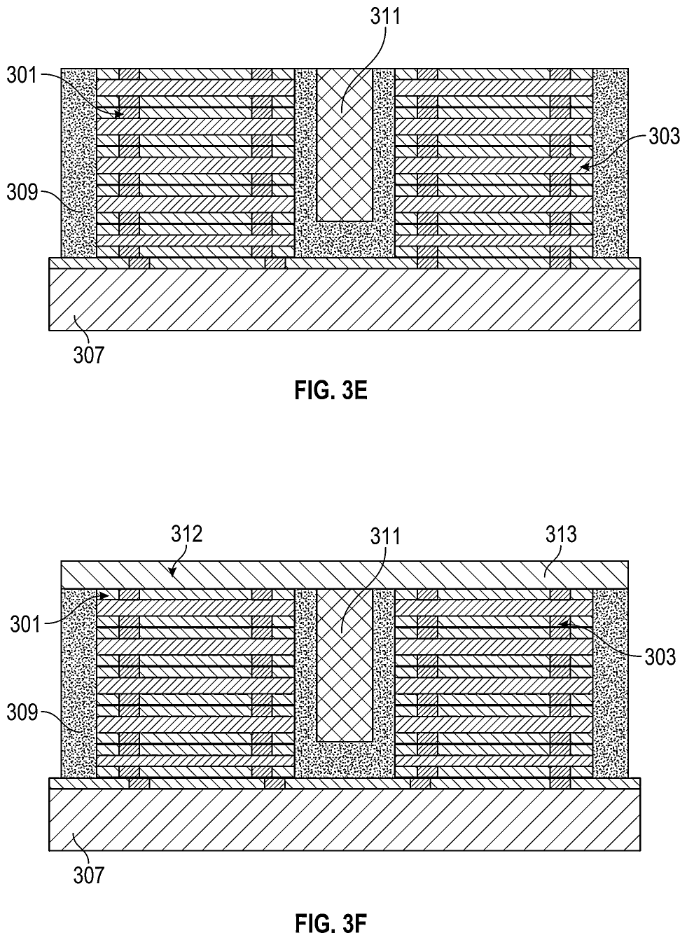

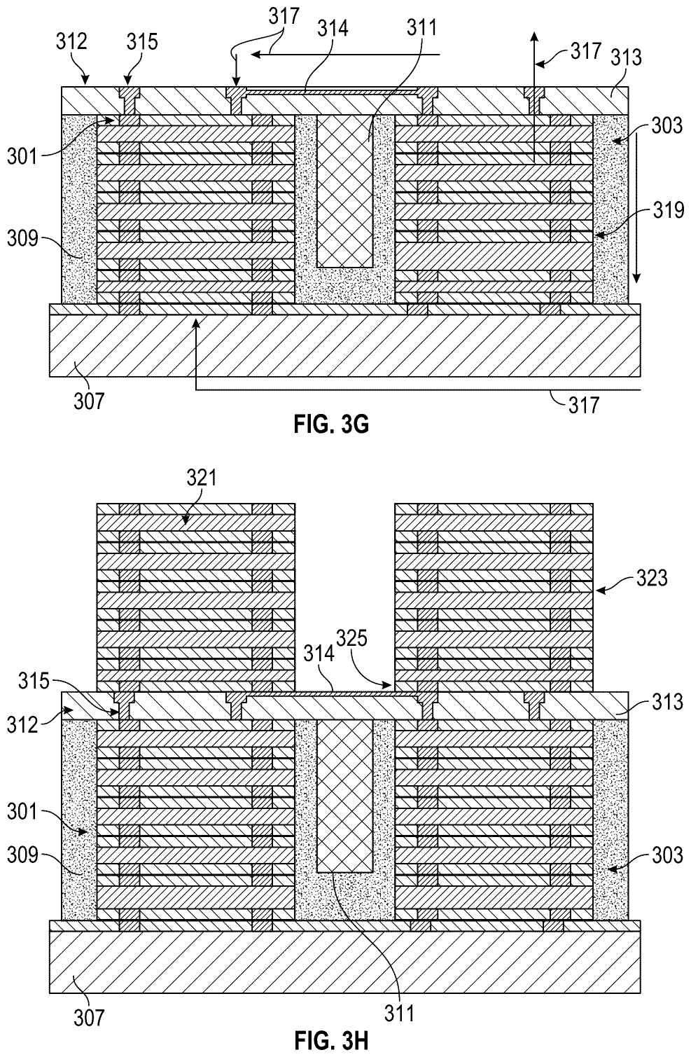

FIGS. 3A-3H illustrate a method for forming a microelectronic structure according to one embodiment. FIG. 3A illustrates a pair of stacks 301 and 303, which may each comprise a plurality of bonded dies 305, bonded (e.g., direct hybrid bonded) to a carrier 307. Unless otherwise noted, the embodiment of FIG. 3A and the method of producing FIG. 3A may be the same or generally similar to like components and structures of FIGS. 2A-2D. For example, the steps of producing the structures of FIG. 3A may be the same as or generally similar to those set forth above in connection with FIGS. 2A-2D.

FIG. 3B illustrates a first protective layer 309 provided over the stacks 301, 303. First protective layer 309 may be provided (e.g., deposited) over carrier 307, first stack 301, and second stack 303. Depositing first protective layer 309 may create a cavity 310 between the first stack 301 and second stack 303 which is empty, e.g. devoid of any material or protective layer 310. The first protective layer 309 may comprise a material with a low coefficient of thermal expansion. The first protective layer 309 can comprise an organic or inorganic nonconductive material. In some embodiment, the first protective layer 309 may comprise a silicon-containing dielectric layer, which may include silicon oxides, silicon nitrides, silicon oxynitrides, silicon carbides, silicon oxycarbides, silicon carbonitrides, or even silicates. In some embodiments, the first protective layer 309 may comprise multiple layers of different dielectric materials. For example, a nitrogen-containing dielectric layer may be coated over the surfaces of the stacked dies 301 and 303 and the exposed bonding surface of the carrier 307. An oxygen-containing dielectric layer may be coated over the nitrogen-containing dielectric layer. In some embodiments, the first protective layer may comprise a particulate composite material. Depending on the nature of the first protective material 309, the exposed surfaces of the stacked dies 301, 303 and the carrier may be treated with a nitrogen bearing plasma prior to the coating of the first protective layer 309. In some embodiments, for example, the first protective layer 309 can comprise an encapsulant or molding compound, such as a nonconductive epoxy. In some embodiments, using a material with a low coefficient of thermal expansion may be advantageous in reducing the stress on the carrier 307. In some embodiment, the thermal expansion of the first protective layer may less than 20 ppm/° C., less than 15 ppm/° C. or less than 10 ppm/° C. In some embodiments, the first protective layer 309 may comprise a porous material or portions of the first protective layer 309 may comprise a porous material. In some embodiments, the substrate of the topmost dies of stack 301 and 303 may comprise embedded through substrate vias (TSVs) (not shown). In this instance, portions of the substrate of the topmost dies may be selectively removed to exposed protruding TSVs with their encapsulating liner layer. The first protective layer 309 can be formed over the exposed surface of the substrates of the topmost dies and the top surface of the carrier 307. In some embodiments, the selective removal of portions of the substrates of the topmost dies may include forming a temporary protective layer over the exposed top surface of the carrier. After the formation of protruded TSVs, the carrier and the bonded die stacks 301 and 303 can be cleaned to remove any unwanted defect forming materials and the temporary protective layer protecting the carrier surface. The cleaned surfaces can then be coated with the first protective layer 309.

During device operation, first stack 301 and second stack 303 may generate heat. Because of the first protective layer's 309 low coefficient of thermal expansion, the heat generated by the first stack 301 and second stack 303 (or the devices in the carrier 307) may not cause as much stress on the carrier 307 or on the stacked devices 301 and 303 as similar structures depicted in FIGS. 2A-2D. This reduction of stress aided by the low coefficient of thermal expansion may also lower the effects of heat or pressures applied during down-stream processing steps, e.g., deposition of further layers, chemical mechanical polishing (CMP), etc. First protective layer 309 may provide lateral support to stacks 301 and 303. In some embodiments, lateral support of stacks 301 and 303 may keep stacks 301 and 303 from being damaged during further processing steps, such as planarization and etching.

FIG. 3C illustrates the planarization of first protective layer 309. First protective layer 309 may be planarized using chemical mechanical processing (CMP) or other suitable methods. The planarization step may comprise polishing of the first protective layer 309 deposited over the back bonding surface of the topmost dies of stacks 301 and 303 to expose or form a planar smooth bonding surface and the embedded conductive pads. In other embodiments, the planarization process may polish off a portion of the first protective layer 309, to form a planar and smooth layer of residual first protective layer over bonding surface of the topmost dies of stack 301 and 303. In some embodiments comprising protruded TSVs embedded in the protective layer 309 as described earlier, the first protective layer 309 can be planarized to remove portions of the first protective layer 302 and portions of the protruded TSVs to expose the conductive layer within the TSVs. Because first protective layer 309 may provide lateral support to stacks 301 and 303, the planarization of the first protective layer 309 may not damage or detrimentally effect the function of stacks 301, 303 and the carrier 307.

FIG. 3D illustrates the deposition of a second protective layer 311. Second protective layer 311 may comprise a material with a low thermal expansion coefficient, such as an inorganic dielectric. The second protective layer 311 may comprise a semiconductor-containing dielectric layer, such as a silicon-containing dielectric layer, which may include silicon oxides, silicon nitrides, silicon oxynitrides, silicon carbides, silicon oxycarbides, and silicon carbonitrides. In some embodiments, the second protective layer 311 may comprise multiple layers of different dielectric materials. For example, a nitrogen bearing dielectric layer may be coated over the surfaces of the stacked dies 301 and 303 and the exposed surface of the carrier 311. An oxygen bearing dielectric layer may be coated over the nitrogen bearing dielectric layer. In some embodiments, the second protective layer may comprise a particulate composite material. Depending on the nature of the second protective material 311, the exposed surfaces of the stacked dies 301, 303 and the first protective layer 309 over the carrier 307 may be treated with a nitrogen bearing plasma prior to the coating of the second protective layer 311. Second protective layer 311 may be provided, e.g., deposited, over and around the pair of stacks 301 and 303 and first protective layer 309. Second protective layer 311 may provide further lateral support to stacks 301 and 303 and reduce the stress of carrier 307 in a similar fashion as first protective layer 309. Second protective layer 311 may also fill cavity, e.g. the empty vertical space, between the first stack 301 and second stack 303. The second protective layer 311 can comprise an organic or inorganic nonconductive material. In some embodiments, for example, the second protective layer 311 can comprise an encapsulant or molding compound, such as a nonconductive epoxy.

FIG. 3E illustrates the planarization of second protective layer 311. Second protective layer 311 may be planarized using chemical mechanical processing (CMP) or other suitable methods. Because second protective layer 311 may provide lateral support to stacks 301 and 303, the planarization of the second protective layer 311 may not damage or detrimentally effect the function stacks 301 and 303. In some embodiments, the second protective 311 layer may not be provided. In such embodiments, the first protective layer 309 may bridge the gap 310 between the first sacked die 30 land the second stacked die 303, and may be adequate for subsequent processing operations after the planarization of the of layer 309.

FIG. 3F illustrates the deposition of a bridging layer 312 including a nonconductive bridge layer 313 over a backside of the first 301 and second 303 stacks and first protective layer 309 and second protective layer 311. The nonconductive bridge layer 313 may comprise a nonconductive layer (e.g., a dielectric layer). Although illustrated as one layer, bridge layer 313 may comprise multiple dielectric layers or sub-layers. The nonconductive bridge layer 313 can comprise an inorganic dielectric in some embodiments, such as silicon oxide, silicon nitride, etc. Bridge layer 313 may be a bridging layer that is deposited over both first stack 301 and second stack 303. Thus, the nonconductive bridge layer 313 may not comprise a separate discrete element that is attached, adhered, or bonded over the stacks 301, 303. Rather, the nonconductive bridge layer 313 may be deposited over the topmost dies 304, portions of the first protective layer 309 (e.g., portions of the first protective layer 309 that are disposed around the respective stacks 301, 303) and portions of the second protective layer 311 (e.g., portions of the second protective layer 311 that are disposed between the portions of the first protective layer 309 between stacks 301, 303.

FIG. 3G illustrates the formation of conductive structures 315 and a conductive interconnect layer 314 in nonconductive bridge layer 313. In some embodiments, the bridging layer 312 may comprise the nonconductive bridge layer 313 with a conductive interconnect layer 314. Conductive structures 315 may be patterned at least partially in nonconductive bridge layer 313 and may be in electrical communication with the first 301 and second stack 303 respectively. A further electrical interconnect layer 314 may be patterned on or at least partially in nonconductive bridge layer 313. Electrical interconnect layer 314 may be configured to electrically connect the first stack 301 with the second stack 303. In some embodiments, the electrical connection between the first stack 301 with the second stack 303 through the electrical interconnect layer 314 may lead to more than one electrical communication paths 317 between dies 319 of the adjacent stacks 301, 303. In some embodiments, dies 319 of the second stack 303 may communicate with dies 319 of the first stack 301 either through the carrier 307 or through the electrical interconnect layer 314. For example, some dies 319 (e.g., dies in an upper portion of the stacks 301, 303) may communicate by way of TSVs in the respective stack 301, 303 and the interconnect layer 314. Other dies 319 (e.g., dies in the lower portion of the stacks 301, 303) may communicate by way of TSVs in the respective stack 301, 303 and traces (not shown) in the carrier 307. In some embodiments, having more than one electrical communication path 317 from the second stack 303 to the first stack 301 may lead to increased signal speed and reduced energy consumption. It should be appreciated that, although two adjacent stacks 301, 303 are shown in FIGS. 3A-3G, in some embodiments, more than two adjacent stacks 301, 303 may be provided on the carrier 307. For example, two, three, four, or more than four die stacks can be provided on the carrier, at least partially encapsulated by the protective layer(s) 309, 311, and electrically connected by the bridging layer 312. In some embodiments, the bridge layer may comprise a planarized nonconductive layer 309 or 311 that bridge the gap 310 between the first conductive dies stack 301 and the second conductive dies stack 303. In this embodiment, conductive structures 315 and a conductive interconnect layer 314 can be formed in nonconductive bridge layer 309 or 311. Conductive structures 315 may be patterned at least partially in nonconductive bridge layer 309 or 311 and may be in electrical communication with the first 301 and second stack 303 respectively. A further electrical interconnect layer 314 may be patterned on or at least partially in nonconductive bridge layer 309 or 311.

In some embodiments, instead of using the deposited conductive interconnect layer 314, wire bonds may be used to form a bridge to electrically connect respective conductive structures 315 to adjacent die stacks. In some embodiments, the conductive interconnect layer 314 may comprise of printed conductive nano metallic particles. In some embodiments, for example, a printed (e.g., deposited0 conductive interconnect layer 314 may comprise silver nanoparticles. After forming the printed (e.g., deposited) circuit, the nano particles of the circuit may be densified by thermal treatment, for example, in an oven or by rapid thermal annealing lamps as in RTP or by laser annealing. In some embodiment the printed circuit may be densified in microwave oven preferably at a temperature lower than 180° C. typically used for the oven treatment temperature. In some embodiments, the electrical resistivity of the printed conductive interconnect layer 314 can be lower than 5 μΩcm, lower than 4 μΩcm, or lower than 3 μΩcm.

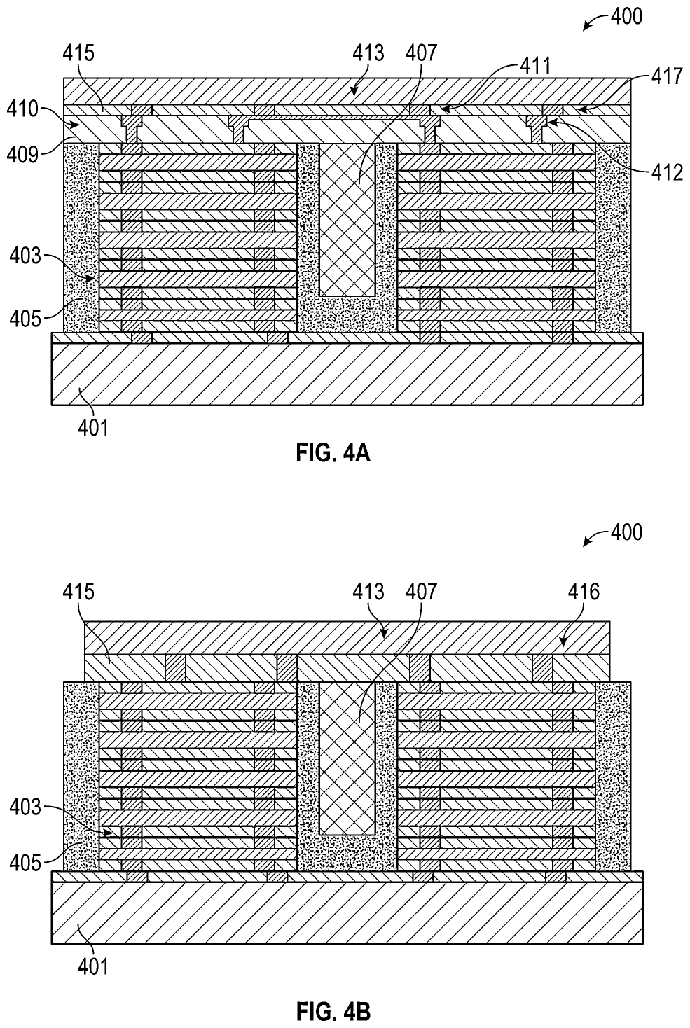

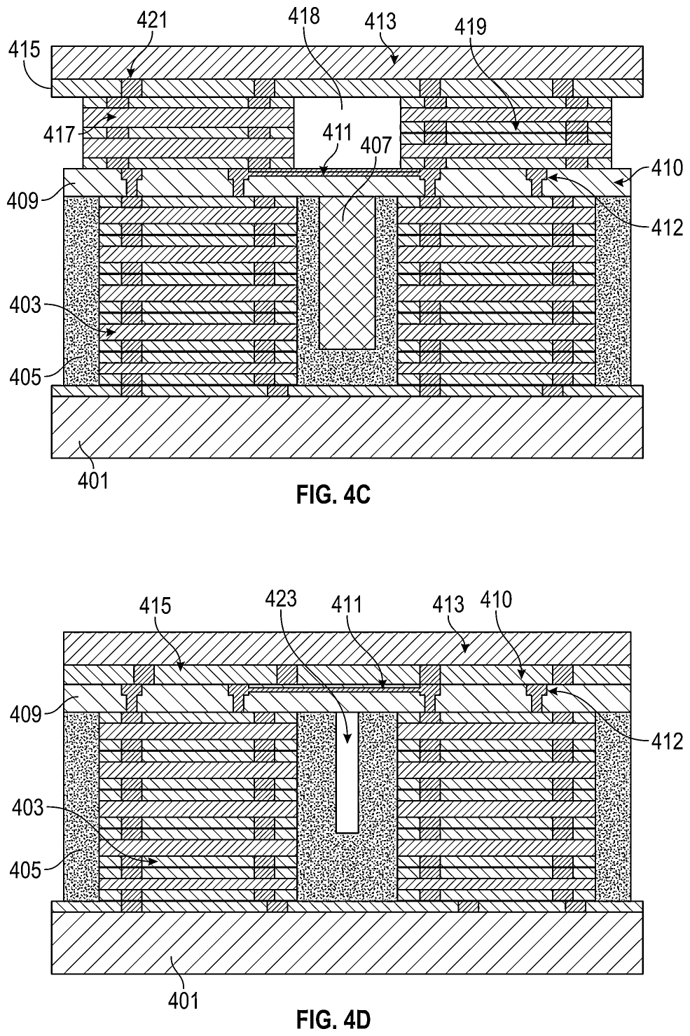

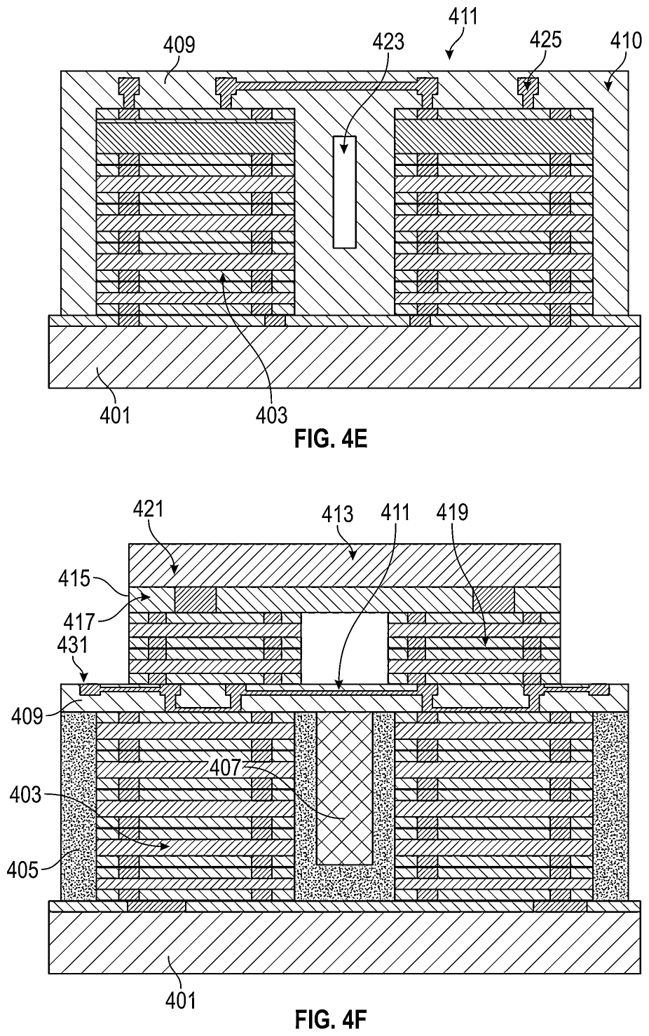

FIG. 3H illustrates the bonding of a third 321 and fourth 323 stacks which may be formed on the top of interconnect layer 314 and bridging layer 312. Similar to first 301 and second stack 303, third 321 and fourth 323 stacks may be formed by bonding dies 325 (e.g., by direct hybrid bonding) to one another as described above. Although both the third stack 321 and fourth stack 323 are illustrated as comprising five (5) dies 325, it should be understood that both third 321 and fourth 323 stacks may comprise more than 5 dies 325 or less than five dies 325. In some embodiments, the nonconductive bridge layer 309, 311 or 314 may comprise test pads 431 as shown in FIG. 4F for testing for example, electrical yields, continuity, electrical resistance and other desirable electrical functionality between the various dies and stacks of FIG. 3H, including circuits in the carrier 307. The electrical testing may be provided to characterize device yields and known good dies before singulation operations. In some embodiments, the structure shown in FIG. 3H can be singulated as explained above into a plurality of devices.

FIGS. 4A-4F illustrate further embodiments that enable the formation of 3D stacks of stacks 403 having multiple electrical communication routes. Unless otherwise noted, the components of FIGS. 4A-4F may be generally similar to the components of FIGS. 3A-3H. For example, as explained above, and as shown in FIG. 4A, a carrier 401, (e.g., a wafer, a substrate, etc.), can have a plurality of stacks 403 bonded to the surface of the carrier 401. As explained above, a first protective layer 405 may be deposited over and around the plurality of stacks 403. The first protective layer 405 may be planarized, and a second protective layer 407 may be deposited over the first protective layer 405 if desired. As above, in some embodiments, the second protective layer 407 may be planarized. A bridging layer 410 may be formed on top of the plurality of stacks 403 and the first 405 and second 407 protective layers or on the first planarized protective layer 405. The bridging layer 410 may comprise a nonconductive bridging layer 409, e.g. a dielectric layer, and a plurality of electrical contact features 412. In other embodiments, a portion the first protective layer 405 may serve as the bridging layer 410 (e.g., a portion of the protective layer 405 may remain disposed over the stacks and patterned with conductors). The nonconductive bridging layer 409 may comprise one or multiple dielectric layers or sublayers. As above, an electrical interconnect structure 411 may be patterned on or at least partially embedded in nonconductive bridging layer 409. Electrical interconnect structure 411 may comprise a plurality of electrical vias and traces and can be configured to electrically connect the plurality of stacks 403 to one another. Unlike in FIG. 3H, a bridging die 413 may be bonded to (e.g., directly hybrid bonded to) the dielectric bridging layer 409. In such embodiments, the bridging layer 410 can serve as a bonding layer, which can be prepared for direct bonding as described herein. The bridging die 413 can be direct hybrid bonded to the bonding surface of the bridging layer 410 in some embodiments. In other embodiments, the bridging die 413 can be attached to the bridging layer 410 with an adhesive, e.g., with solder. Bridging die 413 may comprise a semiconductor device, wafer, or other semiconductor device or element. In some embodiments, bridging die 413 comprises a bonding layer 415, which may be comprise one or more dielectric layers or sublayers. In some embodiments, the bonding layer 415 can be deposited over the bridging layer 410 and directly bonding to a corresponding bonding surface or layer of the die 413. In some embodiments, the bonding layer 415 can be formed on the die 413 and subsequently directly bonded to the bridging layer 410. A series of electrical contact structures 417 may be patterned on or at least partially in bonding layer 415. Bridging die 413 may provide further support to the plurality of stacks 403 and add further desired functionality to the 3D microstructure 400. Bridging die 411 may be in electrical communication or contact with the plurality of stacks 403 as well as the carrier 401.

As shown in FIG. 4B, in some embodiments, a carrier 401 can have a plurality of stacks 403 bonded to the surface of the carrier 401. As explained above, a first protective layer 405 may be deposited over and around the plurality of stacks 403. The first protective layer 405 may be planarized, and a second protective layer 407 may be deposited over the first protective layer 405 if desired. As above, in some embodiments, the second protective layer 407 may be planarized. A bridging element 413 may be bonded to the plurality of stacks 403. A bridging element 413, e.g., a wafer, semiconductor element, integrated circuit device, etc., may comprise a bonding layer 415. Bonding layer 415 may comprise one or more dielectric layers or sub-layers. A plurality of contact features 416 may be at least partially embedded within bonding layer 415. Unlike in FIG. 4A, in FIG. 4B, bridging element 413 may allow for electrical communication between the plurality of stacks 403 through the conductive features in the bonding layer of bridging element 413.

As shown in FIG. 4C, in some embodiments, a structure as described in FIG. 3H may be provided according to the methods explained above. After the structure as described in FIG. 3H is produced, a second plurality of stacks 417, each stack comprising one more dies 419, may be bonded on top of the bridging layer 410. Bridging layer 410 may comprise nonconductive bonding layer 409, e.g., a dielectric layer, and a plurality of contact features 412. A bridging die 413, comprising a bonding layer 415 may be bonded to (e.g., direct hybrid bonded to) the second plurality of stacks 417. Although shown as one layer, bonding layer 415 may comprise on or multiple dielectric layers or sub-layers. Contact structures 421 may be patterned on or at least partially in bonding layer 415. The first plurality of stacks 403 may be in electrical communication with one another through either the dielectric bridging layer 409 or carrier 401. The second plurality of stacks 417 may be in electrical communication with one another either through dielectric bridging layer 409 and/or through the bridging die 413. The second plurality of stacks 417 may be in electrical communication with the first plurality of stacks through dielectric bridging layer 409. As shown in FIG. 4C, the bridging die 413 may bridge a gap 418 between adjacent stacks 417.

As shown in FIG. 4D, in some embodiments, a microstructure similar to the microstructure of FIG. 4B using substantially similar methods and components may be provided. However, unlike in FIG. 4D, After the plurality of stacks 403 are bonded to the carrier 401, a first protective layer 405 may be deposited on and over the plurality of stacks 403 and the carrier 401. First protective layer 405 may be planarized using CMP or other suitable methods, as described above. After first protective layer 405 is planarized, a bridging bonding layer may be deposited over the plurality of stacks 403 and the first protective layer 405, but without the deposition of a second protective layer. Depositing the bridging bonding layer 409 may form a cavity 423 between the plurality of stacks 403. The cavity 423, or inter die cavity, may lead to further flexibility in the carrier 401. Cavity 423 may allow for the microstructures to slightly move and relieve stress built up between the plurality of stacks 403 and on the carrier 401. In some embodiments, the bridging bonding layer may be omitted, or the bridging bonding layer may be fabricated over the surface of bridging die 413. The bridging die 413 may be bonded over the die stacks 401 and 403 for providing communications among all the bonded dies and the carrier 401.

As shown in FIG. 4E, in some embodiments, a structure substantially similar to 3A with substantially similar components may be fabricated. The structure comprises a carrier 401 and a plurality of die stacks 403. After bonding the plurality of die stacks 403, a first protective layer 409 may be deposited over and around the plurality of die stacks 403. Unlike in FIG. 3A, in which the first protective layer 409 would subsequently be covered with a second protective layer, in FIG. 4E, a second protective layer is not provided. Instead, in FIG. 4E, a bridging layer 410 made of the same material as the first protective layer 409, may be provided over protective layer 409. Bridging layer 410 may comprise a plurality of contact structures 425 patterned on or in the bridging layer 410. Similarly, a bridging interconnect structure 411 may be formed at least partially in bridging layer 410. In some embodiments, the electrical contact structures 425 may comprise a redistribution layer. In some embodiments, the redistribution layer or contact structures may be made of copper. In some embodiments, the plurality of stacks 403 may be in electrical communication with the other stacks through the bridging interconnect structure 411 or through carrier 401.

As shown in FIG. 4F, in some embodiments, a structure similar to the structure in FIG. 4C is provided. As described above, a first plurality of stacks 403 may be bonded (e.g., direct hybrid bonded) to a carrier 401. A first protective layer 405 may be deposited over and around the first plurality of die stacks 403. In some embodiments, the first protective layer 405 may be planarized. Then a second protective layer 407 may be deposited over the first protective layer 405. The second protective layer 407 may be planarized and a bridging bonding layer 409 deposited over the first plurality of stacks 403. In some embodiments, the first 405 and second 407 protective layers and the bridging layer 409 may comprise similar or dissimilar dielectric materials. In some embodiment, the first or second protective layer may comprise the bridging layer. A second plurality of stacks 419 may be in turn bonded to bridging bonding layer 409 and a bridging die 413 may be bonded to the second plurality of die stacks 419. However unlike in FIG. 4C, in FIG. 4F, a test pad structure 431 may be patterned into bridging bonding layer 409 and electrically connected to both the electrical interconnect structure 411 as well as the first plurality of die stacks 403 and the second plurality of die stacks 419 and the carrier 401. Test pad structures 431 may allow for a probe, either manual or automatic, to test the functionality of any of the first plurality of die stacks 403, the second plurality of die stacks 419, the carrier 401 or the bridging die 413.

In some embodiments, the stacked structures of FIG. 4F may be encapsulated and the encapsulation can be planarized. The planarized surface may be attached to another carrier (not shown) to expose the back surface of the carrier 401. The back surface of the carrier can be processed for bonding to the bridging layer 409 of another substrate such as that shown in FIG. 4E. The resulting structure can comprise more than one bridging layer 409. The bridging layers 409 can serve as an interposer(s) interconnecting the arrays of stacked dies on both sides of the bridging layer 409. Processing the backside of carrier 401 may comprise thinning, polishing, and exposing embedded conductors in the carrier 401. In some embodiments, a planar bonding surface with embedded conductors may be formed on the backside of the carrier 401. In some embodiment the backside of the carrier 401 may comprise a solderable mass or alloy mass. Similarly, depending on design parameters, a solderable mass or alloy mass may be disposed as conductive features on the bridging layer 409.

### Examples of Direct Bonding

Various embodiments disclosed herein relate to directly bonded structures in which two elements can be directly bonded to one another without an intervening adhesive. A directly bonded structure comprises two elements and that can be directly bonded to one another without an intervening adhesive. Two or more semiconductor elements (such as integrated device dies, wafers, etc.) may be stacked on or bonded to one another to form a bonded structure. Conductive contact pads of a first element may be electrically connected to corresponding conductive contact pads of a second element. Any suitable number of elements can be stacked in the bonded structure. For example, a third element can be stacked on the second element, a fourth element can be stacked on the third element, and so forth. Additionally, or alternatively, one or more additional elements can be stacked laterally adjacent one another along the first element. In some embodiments, the laterally stacked additional element may be smaller than the second element. In some embodiments, the laterally stacked additional element may be two times smaller than the second element.

In some embodiments, the elements are directly bonded to one another without an adhesive. In various embodiments, a non-conductive or dielectric material can serve as a first bonding layer of the first element which can be directly bonded to a corresponding non-conductive or dielectric field region serving as a second bonding layer of the second element without an adhesive. The non-conductive bonding layers can be disposed on respective front sides of a device, such as a semiconductor (e.g., silicon) portion of the elements. Active devices and/or circuitry can be patterned and/or otherwise disposed in or on the device portions. Active devices and/or circuitry can be disposed at or near the front sides of the device portions, and/or at or near opposite backsides of the device portions. The non-conductive material can be referred to as a non-conductive bonding region or bonding layer of the first element. In some embodiments, the non-conductive bonding layer of the first element can be directly bonded to the corresponding non-conductive bonding layer of the second element using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SICOH dielectrics, silicon carbonitride or diamond-like carbon or a material comprising of a diamond surface. Such carbon-containing ceramic materials can be considered inorganic, despite the inclusion of carbon.

In various embodiments, direct hybrid bonds can be formed without an intervening adhesive. For example, nonconductive bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma to activate and terminate the surfaces. In other embodiments, the bonding surface can be terminated in a separate treatment to provide the additional species for direct bonding. In various embodiments, the terminating species can comprise nitrogen. For example, in some embodiments, the bonding surface(s) can be exposed to a nitrogen-containing plasma. Further, in some embodiments, the bonding surfaces can be exposed to fluorine. For example, there may be one or multiple fluorine peaks near layer and/or bonding interface. Thus, in the directly bonded structure, the bonding interface between two non-conductive materials (e.g., the bonding layers) can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along the bond interface that includes covalently direct bonded non-conductive-to-non-conductive (e.g., dielectric-to-dielectric) surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, non-conductive (e.g., dielectric) bonding surfaces (for example, inorganic dielectric surfaces) can be prepared and directly bonded to one another without an intervening adhesive as explained above. Conductive contact features (e.g., contact pads which may be surrounded by non-conductive dielectric field regions within the bonding layers) may also directly bond to one another without an intervening adhesive. In various embodiments, the conductive contact features can comprise discrete pads at least partially embedded in the nonconductive field regions. In some embodiments, the conductive contact features can comprise exposed contact surfaces of through substrate vias (TSVs). In some embodiments, the respective contact pads 106a and 106b can be recessed below exterior (e.g., upper) surfaces of the dielectric field or non-conductive bonding layers, for example, recessed by less than 30 nm, less than 20 nm, less than 15 nm, or less than 10 nm, for example, recessed in a range of 2 nm to 20 nm, or in a range of 4 nm to 10 nm. In various embodiments, prior to direct bonding, the recesses in the opposing elements can be sized such that the total gap between opposing contact pads is less than 15 nm, or less than 10 nm. The non-conductive bonding layers can be directly bonded to one another without an adhesive at room temperature in some embodiments and, subsequently, the bonded structure can be annealed. Upon annealing, the contact pads can expand and contact one another to form a metal-to-metal direct bond. Beneficially, the use of Direct Bond Interconnect, or DBI®, techniques commercially available from Xperi of San Jose, CA, can enable high density of pads to be connected across the direct bond interface (e.g., small or fine pitches for regular stacks). In some embodiments, the pitch of the pads, or conductive traces embedded in the bonding surface of one of the bonded elements, may be less than 40 microns or less than 10 microns or even less than 2 microns. For some applications, the ratio of the pitch of the bonding pads 106a and 106b to one of the dimensions (e.g., a diameter) of the bonding pad is less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, as shown in, the first element can comprise a carrier or substrate (e.g., a wafer) that includes a plurality (e.g., tens, hundreds, or more) of device regions that, when singulated, form a plurality of integrated device dies. Similarly, the second element 104 can comprise a singulated element, such as a singulated integrated device die. In other arrangements, the second element can comprise a carrier or substrate (e.g., a wafer). The embodiments disclosed herein can accordingly apply to wafer-to-wafer, die-to-die, or die-to-wafer bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the singulation process (e.g., saw markings if a saw singulation process is used).

As explained herein, the first and second elements can be directly bonded to one another without an adhesive, which is different from a deposition process. In one application, a width of the first element in the bonded structure is similar to a width of the second element. In some other embodiments, a width of the first element in the bonded structure is different from a width of the second element. Similarly, the width or area of the larger element in the bonded structure may be at least 10% larger than the width or area of the smaller element. The first and second elements and can accordingly comprise non-deposited elements. Further, directly bonded structures, unlike deposited layers, can include a defect region along the bond interface 118 in which nanometer-scale voids (nanovoids) are present. The nanovoids may be formed due to activation of the bonding surfaces and (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolized (OH-terminated) surface with NH 2 molecules, yielding a nitrogen-terminated surface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers 108a and 108b can also comprise polished surfaces that are planarized to a high degree of smoothness.

In various embodiments, the metal-to-metal bonds between the contact pads can be joined such that copper grains grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the non-conductive bonding layers at or near the bonded contact pads. In some embodiments, a barrier layer may be provided under the contact pads (e.g., which may include copper). In other embodiments, however, there may be no barrier layer under the contact pads, for example, as described in U.S. Pat. No. 11,195,748, which is incorporated by reference herein in its entirety and for all purposes.

Beneficially, the use of the hybrid bonding techniques described herein can enable extremely fine pitch between adjacent contact pads, and/or small pad sizes. For example, in various embodiments, the pitch p (i.e., the distance from edge-to-edge or center-to-center between adjacent pads can be in a range of 0.5 microns to 50 microns, in a range of microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of microns to 5 microns, or in a range of 0.5 microns to 5 microns.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonded structure comprising:
a carrier;
a first plurality of die stacks, each die stack comprising a plurality of dies, each die stack of the first plurality of die stacks bonded to the carrier;
a protective layer over at least a portion of the first plurality of die stacks; and
a bridging layer comprising a nonconductive bridge layer and a lateral conductive interconnect;
wherein the lateral conductive interconnect provides electrical communication between the first plurality of die stacks.

2. The bonded structure of claim 1, further comprising a plurality of contact features at least partially embedded in the nonconductive bridge layer,
wherein the lateral conductive interconnect provides electrical communication between at least two of the plurality of contact features.

3. The bonded structure of claim 1, further comprising at least one die stack directly bonded without an adhesive to the bridging layer.

4. The bonded structure of claim 1, further comprising a second plurality of die stacks directly bonded to the bridging layer and a bridging element directly bonded to the second plurality of die stacks.

5. The bonded structure of claim 4, further comprising at least one test pad at least partially embedded in the bridging layer, wherein the test pad is in electrical communication with the first plurality of stacks and the second plurality of stacks.

6. The bonded structure of claim 1, further comprising a bridging element directly bonded, without an adhesive, to the bridging layer.

7. The bonded structure of claim 6, further comprising a cavity between a first stack and a second stack.

8. The bonded structure of claim 1, wherein each stack of the first plurality of stacks comprises a first die bonded to a second die, without an adhesive.

9. The bonded structure of claim 1, wherein a first nonconductive bonding layer of at least one stack of the plurality stacks is directly bonded to a second nonconductive bonding layer of the carrier without an intervening adhesive,
and wherein a first contact feature of at least one stack of the plurality stacks is directly bonded to a second contact feature of the carrier without an intervening adhesive.

10. The bonded structure of claim 1, wherein a material of the protective layer is the same as a material of the bridging layer.

11. A bonded structure comprising:
a first die stack comprising a first plurality of dies;
a second die stack comprising a second plurality of dies;
a protective layer disposed at least about lateral sides of the first and second die stacks and between the first and second die stacks; and
a bridging layer disposed over the first die stack, the second die stack, and the protective layer, the bridging layer providing electrical communication between at least one die of the first die stack and at least one die of the second die stack.

12. The bonded structure of claim 11, wherein the first plurality of dies within the first die stack are direct hybrid bonded.

13. The bonded structure of claim 11, wherein the second plurality of dies within the second die stack are direct hybrid bonded.

14. The bonded structure of claim 11, wherein the first die stack and the second die stack are direct hybrid bonded to a carrier.

15. The bonded structure of claim 11, wherein the first die stack and the second die stack are direct hybrid bonded to a bridging element.

16. The bonded structure of claim 15, further comprising a third die stack comprising a third plurality of dies, wherein the third die stack is direct hybrid bonded to the bridging layer, and a fourth die stack comprising a fourth plurality of dies, wherein the fourth die stack is direct hybrid bonded to the bridging layer.

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. A bonded structure comprising:
a carrier having a nonconductive layer and conductive features at least partially embedded in the nonconductive layer;
a first die stack having a first top die and a first bottom die, the first top and first bottom dies of the first die stack each having a respective nonconductive layer and conductive features, the first bottom die of the first die stack bonded to the carrier;
a bridging layer comprising a nonconductive layer and a conductive interconnect, the bridging layer disposed over the first top die of the first stack; and
a second die stack having a second bottom die direct hybrid bonded to an upper surface of the bridging layer,
wherein the conductive interconnect of the bridging layer provides electrical communication between the first and second die stacks.

32. The bonded structure of claim 31, further comprising a third die stack bonded to the carrier, the bridging layer disposed over a third top die of the third stack.

33. The bonded structure of claim 31, wherein the conductive interconnect of the bridging layer comprises a printed wire.

34. The bonded structure of claim 31, further comprising a wire bond that connects the first and second die stacks.
